(19) United States
(12) Patent Application Publication
(10) Pub. No.: US 2026/0112940 A1
(43) Pub. Date: Apr. 23, 2026

(54) SYSTEMS AND METHODS FOR COOLING USING INTEGRATION OF PRESSURE DIFFERENCE COOLING AND PULSATING HEAT PIPE

(71) Applicant: Toyota Motor Engineering & Manufacturing North America, Inc., Plano, TX (US)

(72) Inventors: Shailesh N. Joshi, Ann Arbor, MI (US); Danny J. Lohan, West Bloofmield, MI (US)

(73) Assignee: Toyota Motor Engineering & Manufacturing North America, Inc., Plano, TX (US)

(21) Appl. No.: 18/920,225

(22) Filed: Oct. 18, 2024

(51) Int. Cl. H02K 5/20; B64D 27/30; H02K 9/10; H02K 9/22

(52) U.S. Cl. CPC H02K 5/20; B64D 27/30; H02K 9/10; H02K 9/225; H02K 9/227

(57) ABSTRACT

The present disclosure is directed a cooling system. The cooling system includes a casing and at least two fins. The casing surrounds one or more electronic devices. The at least two fins extending from an exterior surface of the casing. Each of the at least two fins configured to direct an airflow to generate a high pressure zone and a low pressure zone. The casing includes a duct assembly that has a duct inlet and a duct outlet. The duct inlet is configured to be positioned in the high pressure zone and the duct outlet is configured to be positioned in the low pressure zone.

### TECHNICAL FIELD

The present specification generally relates to apparatuses for cooling structures and, more specifically, to apparatuses for cooling structures that use pressure differential to increase airflow.

### BACKGROUND

Electric aircraft rely on motors to generate lift and/or thrust. Electric aircraft also use a variety of other electronic devices, such as motors and inverters, to control aircraft functions and complete various tasks. One type of electric aircraft can be an electric vertical takeoff and landing vehicle (eVTOL). These electronic devices can be packaged together within a casing. These electronic devices can generate significant heat which requires cooling in order to keep the electronics within their optimal operating temperature range. Conventional cooling systems can involve using the surface of the casing and cooling fins to spread heat, among other types of cooling devices. Conventional cooling systems can result in poor heat spreading capability around the surface of the package of electronics, which can result in lower cooling effectiveness and lower electronic functionality.

### SUMMARY

In one embodiment, a cooling system is provided. The cooling system includes a casing and at least two fins. The casing surrounds one or more electronic devices. There are at least two fins extending from an exterior surface of the casing. Each of the at least two fins configured to direct an airflow to generate a high pressure zone and a low pressure zone. The casing includes a duct assembly that has a duct inlet and a duct outlet. The duct inlet is configured to be positioned in the high pressure zone and the duct outlet is configured to be positioned in the low pressure zone.

In another embodiment, an electric motor assembly is provided. The electric motor assembly includes a motor housing, a motor within the motor housing, a casing, one or more electronic devices, and at least two fins. The casing has an exterior surface and an opposite interior surface that defines a casing interior cavity. The one or more electronic devices are positioned within the casing interior cavity to be surrounded by the interior surface. There are at least two fins extending from the exterior surface of the casing. Each pair of the at least two fins and the exterior surface of the casing define a fin interior cavity. Each of the at least two fins are configured to direct an airflow to generate a high pressure zone and a low pressure zone. The casing includes a duct assembly that has a duct inlet and a duct outlet. The duct inlet is configured to be positioned in the high pressure zone and the duct outlet is configured to be positioned in the low pressure zone.

In yet another embodiment, an electric vertical takeoff and landing vehicle is provided. The electric vertical takeoff and landing vehicle includes an electric motor assembly. The electric motor assembly includes a motor housing, a motor within the motor housing, a casing, one or more electronic devices, and at least two fins. The casing has an exterior surface and an opposite interior surface that defines a casing interior cavity. The one or more electronic devices are positioned within the casing interior cavity to be surrounded by the interior surface. There are at least two fins extending from the exterior surface of the casing. Each pair of the at least two fins and the exterior surface of the casing define a fin interior cavity. Each of the at least two fins are configured to direct an airflow to generate a high pressure zone and a low pressure zone. The casing includes a duct assembly that has a duct inlet and a duct outlet. The duct inlet is configured to be positioned in the high pressure zone and the duct outlet is configured to be positioned in the low pressure zone.

These and additional features provided by the embodiments described herein will be more fully understood in view of the following detailed description, in conjunction with the drawings.

### BRIEF DESCRIPTION OF THE DRAWINGS

The embodiments set forth in the drawings are illustrative and exemplary in nature and not intended to limit the subject matter defined by the claims. The following detailed description of the illustrative embodiments can be understood when read in conjunction with the following drawings, where like structure is indicated with like reference numerals and in which:

FIG. 1 schematically depicts a system that includes front section view of a motor, a casing, a plurality of fins, and a propeller assembly, according to one or more embodiments shown and described herein;

FIG. 2 schematically depicts a partial isolated view of a pulsating heat pipe embedded within a fin and coupled to the casing inner surface, according to one or more embodiments shown and described herein;

FIG. 3A schematically depicts a partial cross sectional view of the example two-part cooling system of FIG. 2 taken from line 3A-3A, according to one or more embodiments shown and described herein;

FIG. 3B schematically depicts a cross sectional view of the example two-part cooling system of FIG. 2 taken from line 3B-3B, according to one or more embodiments shown and described herein;

FIG. 3C schematically depicts a front plan view of the example two-part cooling system of FIG. 2, according to one or more embodiments shown and described herein;

FIG. 3D schematically depicts a top-down view of the example two-part cooling system of FIG. 2, according to one or more embodiments shown and described herein;

FIG. 3E schematically depicts a top-down cross sectional view of the example two-part cooling system of FIG. 3D taken from line 3E-3E, according to one or more embodiments shown and described herein;

FIG. 4 schematically depicts the partial cross sectional view of the example two-part cooling system of FIG. 2 taken from line 3A-3A now illustrating an airflow path, according to one or more embodiments shown and described herein;

FIG. 5 schematically depicts a partial cross sectional view of the example two-part cooling system of FIG. 4 taken from line 5-6 illustrating conduction and convention heat transfer of the airflow, according to one or more embodiments shown and described herein; and

FIG. 6 schematically depicts an eVTOL with the example two-part cooling system of FIG. 1, according to one or more embodiments shown and described herein.

### DETAILED DESCRIPTION

Embodiments of the present disclosure are directed to a cooling system for an electric vertical takeoff and landing vehicle (eVTOL). The eVTOL includes a motor and an inverter package. The package may include a metal casing, in which various electronic devices may be housed. One or more fins may be coupled to the outer surface of the casing. The cooling system may use a two-part cooling structure, where one part includes a pulsating heat pipe (PHP) assembly partially embedded within the casing, and a second part includes a series of ductworks through the casing which use pressure differential to increase airflow around the casing and fins to increase heat transfer.

A duct inlet may be mounted between two fins of a plurality of external fins mounted on an exterior surface of the casing. The duct inlet may allow airflow through interior channels built within the casing. The airflow may be vented out of the casing through a duct outlet. The duct inlet and duct outlet may be positioned such that the orientation of the plurality of fins surrounding the duct inlet and duct outlet create a high pressure zone near the duct inlet and a low pressure zone near the duct outlet, which may increase the airflow through the ducts and through the channels. For example, the angle of attack of the plurality of fins may be positioned so as to create this pressure differential. This airflow will help transfer heat from electronic devices mounted inside of the casing. In some embodiments, the PHP may be embedded within the casing and the fins. The PHP may contain alternating slugs of liquid and vapor which may further enhance the cooling effect of the cooling system by increasing the heat transfer from the electronic devices to the fins.

Conventional cooling systems can limit heat spread and concentrate heat at the portion of the casing and fin closest to the heat source. This does not efficiently use the full area of the casing and fin as heat is not dissipated across the entire casing and fin, and also removes less heat from the heat source the casing and fin are designed to cool compared to the present system. The two-part cooling structure, where one part includes a pulsating heat pipe (PHP) assembly at least partially embedded within the fins, and the second part includes a series of ductworks through the casing which use pressure differential to increase airflow around the casing and fins to increase heat transfer to more effectively transfer heat throughout the entire casing and fin to more efficiently use the total area of the casing and fin and to increase the spread of heat throughout the entire casing and fin compared to conventional cooling systems. Advantageously, the cooling system described herein utilizes two-phases heat transfer mechanisms to remove heat from at least one heat generating device. The first heat transfer mechanism is configured to utilize pulsating heat pipe to efficiently move heat across heat pipes through the case. The second mechanism redirects airflow into a cavity of the case, thereby reducing a thermal resistance between the heat generating device and airflow to improve heat transfer.

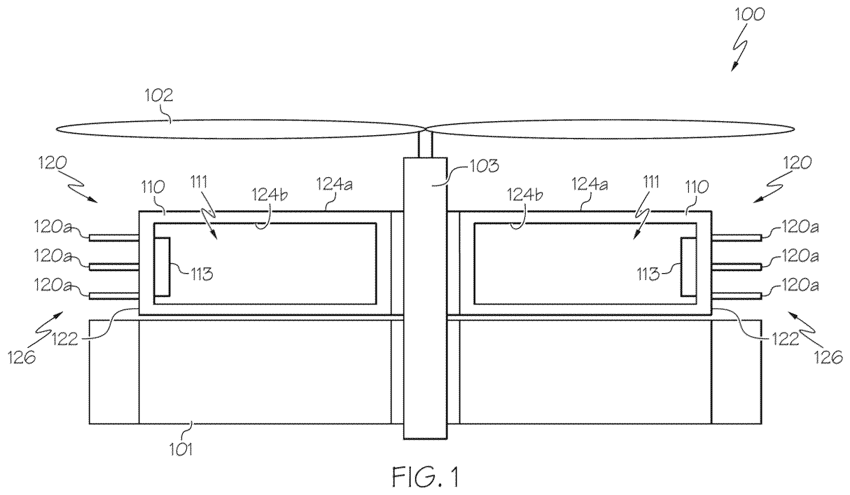

Referring now to FIG. 1, an example embodiment of a system 100 is shown. The system 100 includes a casing 110, a motor 101, one or more electronic devices 113, a propeller 102, a propeller shaft 103, and an example two-part cooling system 126. The one or more electronic devices 113 are disposed within the casing interior cavity 111 (i.e. an enclosure). That is, one or more electronic devices 113 are surrounded or encased by the casing 110. A plurality of fins 120 extend from the outside of the casing 110. The propeller shaft 103 is coupled to the motor 101 and the propeller 102. Casing 110 may have a pass through 117 to allow the propeller shaft 103 to pass from motor 101 to propeller 102. Propeller 102 may provide lift, thrust, or a combination of lift and thrust. Any number of fins of the plurality of fins 120 may be included. It should be understood the arrangement of components of the system 100 of FIG. 1 is for illustrative purposes, and that other arrangements are possible.

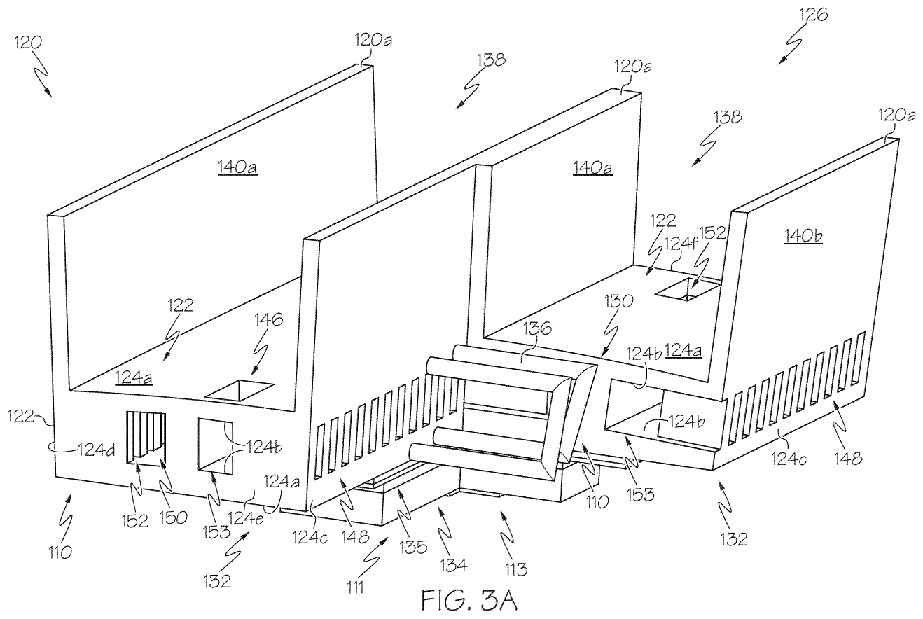

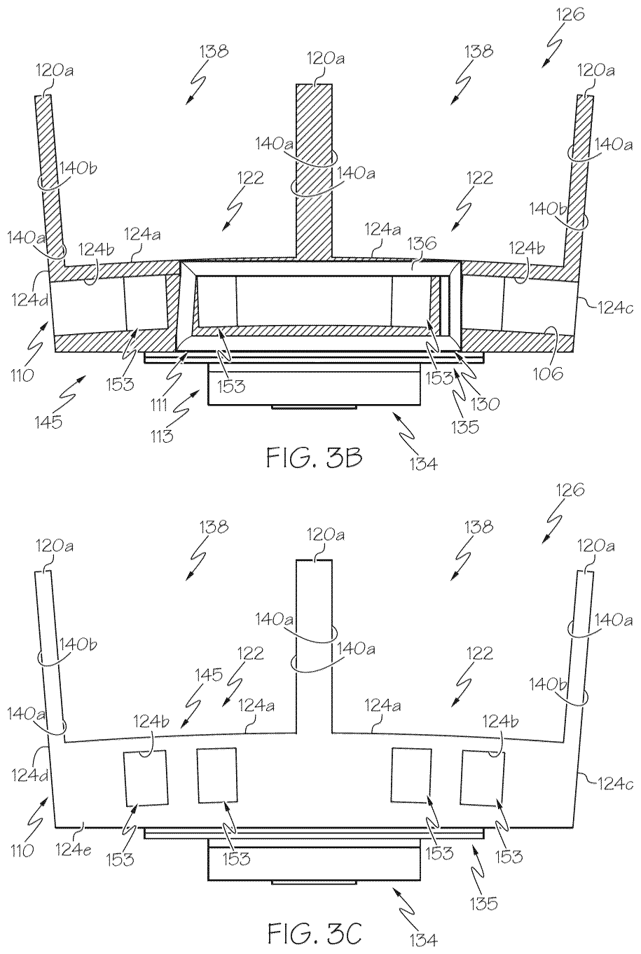

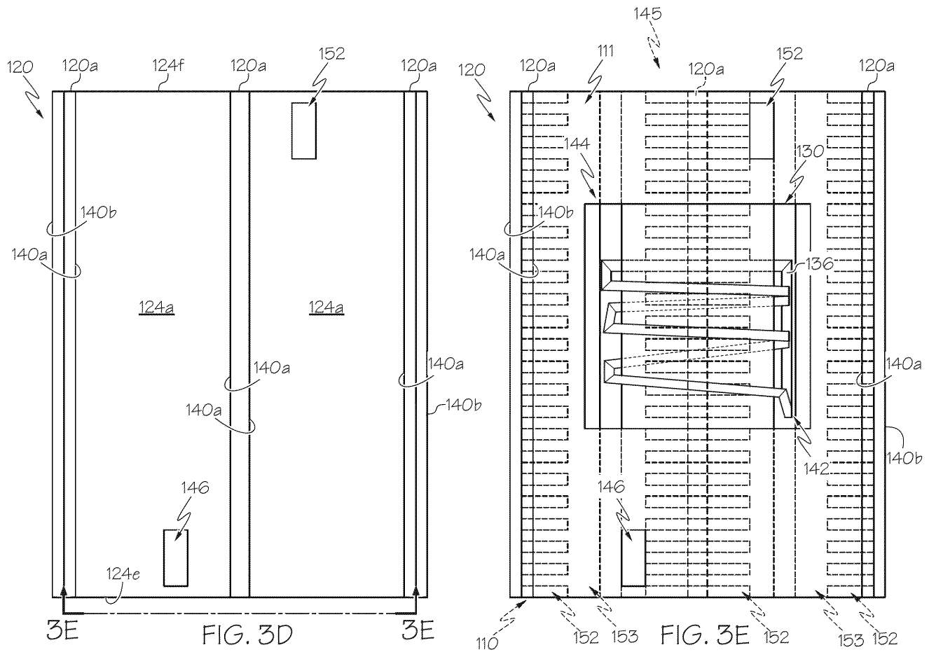

The one or more electronic devices 113 positioned in the casing interior cavity 111 can be one or more different electronic devices 113. The one or more electronic devices 113 included may be an inverter package or circuit, a gate drive, and/or the like. Alternatively, or in addition, the one or more electronic devices 113 may also include a capacitor, an insulated-gate bipolar transistor, a power MOSFET, or any other electronic devices. The one or more electronic devices 113 may be a power device package 134 (FIG. 3A) that may include various layers 135 (FIG. 3A), such as, and without limitation, thermal conductors, electrical isolation, and thermal interface layers. The one or more electronic devices 113 can be a heat source of the system 100, wherein the electronics generate heat during operation.

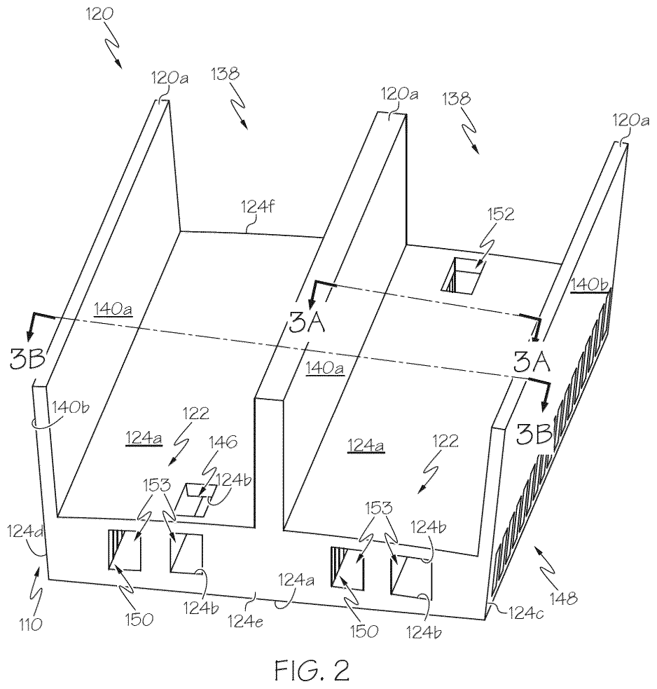

Now referring to FIGS. 2 and 3A-3E, the casing 110 surrounding the one or more of electronic devices 113 can be any number of shapes, including but not limited to a cylinder, a toroid, a rectangular prism, and/or the like. The casing 110 can be made of any number of materials, including but not limited to aluminum, steel, plastic, and the like. The casing 110 includes a wall 122 that includes an exterior surface 124a and an interior surface 124b opposite of the exterior surface 124a, a pair of sidewall surfaces 124c, 124d, and a pair of terminating end surfaces 124e, 124f to define the casing interior cavity 111. That is, in some embodiments, the wall 122 may be continuous. In other embodiments, multiple wall sections define the wall 122. In some embodiments, there may be a plurality of casings 110 arranged together wherein each casing 110 has at least one fin 120a of the plurality of fins 120 attached to it.

In some embodiments, the casing 110 and components thereof may be formed using additive manufacturing techniques or processes such as 3D printing, As used herein, the terms “additive manufacturing techniques or processes” refer generally to manufacturing processes wherein successive layers of material(s) are provided on each other to “build-up,” layer-by-layer, a three-dimensional component. The successive layers generally fuse together to form a monolithic component which may have a variety of integral sub-components. Although additive manufacturing technology is described herein as enabling fabrication of complex objects by building objects point-by-point, layer-by-layer, typically in a vertical direction, other methods of fabrication are possible and within the scope of the present subject matter. For example, although the discussion herein refers to the addition of material to form successive layers, one skilled in the art will appreciate that the methods and structures disclosed herein may be practiced with any additive manufacturing technique or manufacturing technology. For example, embodiments of the present invention may use layer-additive processes, layer-subtractive processes, or hybrid processes.

Suitable additive manufacturing techniques in accordance with the present disclosure include, for example, Fused Deposition Modeling (FDM), Selective Laser Sintering (SLS), 3D printing such as by inkjets and laserjets, Sterolithography (SLA), Direct Selective Laser Sintering (DSLS), Electron Beam Sintering (EBS), Electron Beam Melting (EBM), Laser Engineered Net Shaping (LENS), Laser Net Shape Manufacturing (LNSM), Direct Metal Deposition (DMD), Digital Light Processing (DLP), Direct Selective Laser Melting (DSLM), Selective Laser Melting (SLM), Direct Metal Laser Melting (DMLM), and other known processes.

The additive manufacturing processes described herein may be used for forming components using any suitable material. For example, the material may be plastic, metal, concrete, ceramic, polymer, epoxy, photopolymer resin, or any other suitable material that may be in solid, liquid, powder, sheet material, wire, or any other suitable form. More specifically, according to exemplary embodiments of the present subject matter, the additively manufactured components described herein may be formed in part, in whole, or in some combination of materials including but not limited to pure metals, nickel alloys, chrome alloys, titanium, titanium alloys, magnesium, magnesium alloys, aluminum, aluminum alloys, and nickel or cobalt base superalloys (e.g., those available under the name Inconel® available from Special Metals Corporation). These materials are examples of materials suitable for use in the additive manufacturing processes described herein, and may be generally referred to as “additive materials.”

In addition, one skilled in the art will appreciate that a variety of materials and methods for bonding those materials may be used and are contemplated as within the scope of the present disclosure. As used herein, references to “fusing” may refer to any suitable process for creating a bonded layer of any of the above materials. For example, if an object is made from polymer, fusing may refer to creating a thermoset bond between polymer materials. If the object is epoxy, the bond may be formed by a crosslinking process. If the material is ceramic, the bond may be formed by a sintering process. If the material is powdered metal, the bond may be formed by a melting or sintering process. One skilled in the art will appreciate that other methods of fusing materials to make a component by additive manufacturing are possible, and the presently disclosed subject matter may be practiced with those methods.

In other embodiments, the casing 110 may be formed by casting, machining, or any other suitable manufacturing technique.

In some embodiments, each fin 120a can be mounted to the casing 110, such as extending from the exterior surface 124a. Each fin 120a can be mounted to the casing 110 may be mounted to and positioned to extend between the terminating end surfaces 124e, 124f and between the sidewall surfaces 124c, 124d, respectively. As such, in some embodiments, each fin 120a may extend a length of the exterior surface 124a of the casing 110 between the terminating end surfaces 124e, 124f. This is non-limiting and in other embodiments, each fin 120a may have a uniform length or may be any length and not necessarily equal to lengths of other fins 120a.

Each fin 120a can be mounted to the casing 110 by various methods, including but not limited to soldering, brazing, and welding. In other embodiments, each fin 120a and the casing 110 may be made from a single piece of material. That is, each fin 120a may be integrated with the casing 110 as a single monolithic structure. In some embodiments, the each fin 120a and the casing 110 may be formed from additive manufacturing techniques or processes such as 3D printing. In other embodiments, each fin 120a and/or the casing 110 may be formed by casting, machining, or any other suitable manufacturing technique.

Each fin 120a can be any number of shapes, including but not limited to a cylinder, rectangular prism, rectangular, square, and/or the like. Further, each fin 120a may be planar in shape or may extend in multiple angles or directions with respect to a Cartesian coordinate system and the exterior surface 124a (e.g., the shape may be manipulated). Each fin 120a of the plurality of fins 120 are configured to induce a pressure differential from one side to the other, as discussed in greater detail herein.

Still referring to FIGS. 2, 3A-3E and 5, the example two-part cooling system 126 includes a pulsating heat pipe assembly 130 and a duct assembly 132. The pulsating heat pipe assembly 130 may include at least one pulsating heat pipe 136 fluidly coupled to the interior surface 124b of the casing 110 and may be embedded within the casing interior cavity 111 and/or within the thickness of the casing 110 between the interior surface 124b and the exterior surface 124a. In other embodiments, the at least one pulsating heat pipe 136 may be at least partially embedded within a fin interior cavity 138 defined by an inner surface 140a of a pair of adjacent fins 120a of the plurality of fins 120 and the exterior surface 124a of the casing 110. Each fin 120a further includes an opposite outer surface 140b. In other embodiments, at least a portion of the at least one pulsating heat pipe 136 may be positioned within and/or fluidly coupled to the fin interior cavity 138.

At least portions of the at least one pulsating heat pipe 136 may also be positioned within and/or may be fluidly coupled to the interior surface 124b of the casing 110 and different portions may be also, or alternatively, be positioned within and/or fluidly coupled to the fin interior cavity 138 by any number of methods, including but not limited to, solder or thermal grease. It should be appreciated that the thermal grease may allow for more efficient heat transfer between the at least one pulsating heat pipe 136 and the interior surface 124b of the casing 110 and/or the fin interior cavity 138. In other embodiments, the at least one pulsating heat pipe 136 may be fluidly coupled to the interior surface 124b of the casing 110 and/or may be fluidly coupled to the fluidly coupled to the fin interior cavity 138 via a snap fit, and/or via fasteners, such as, without limitation, screw, rivet, nut and bolt, weld, adhesive, and the like.

The pulsating heat pipe assembly 130 may be in a closed loop configuration and may further include an evaporator section 142, which may be positioned adjacent to the one or more electronic devices 113 on or within the casing interior cavity 111 that may be defined by the interior surface 124b. As a non-limiting example, R404A may be used as a refrigerant that passes through the pulsating heat pipe assembly 130. As the one or more electronic devices 113 generates heat during operation, this heat is transferred to the evaporator section 142 of the pulsating heat pipe assembly 130. A condenser section 144 of the pulsating heat pipe assembly 130 may be positioned to be distanced away from the one or more electronic devices 113 and, in some embodiments, within the airflow of propeller 102 (not shown). The refrigerant can travel between the evaporator section 142 and condenser section 144, transforming between vapor phase and liquid phase. Such transformation can absorb and release heat, resulting in heat being absorbed from the one or more electronic devices 113 and vapor released from the casing 110. This arrangement may provide the advantage of higher heat transfer capability, spreading of high heat flux, ability to withstand g-forces experienced by an aircraft, performance insensitivity to orientation, and simplicity of structure.

In the embodiment shown in FIGS. 3A-3E, the pulsating heat pipe assembly 130 is embedded within two adjoining or adjacent casings 110 and is configured to the absorb heat from the one or more electronic devices 113 and release vapor from the casing 110 the duct assembly 132, as discussed in greater detail herein. It should be understood that the pulsating heat pipe assembly 130 can be embedded within any suitable number of the casings 110, within the interior cavity 111, and/or the like. In other embodiments, the system 100 may include a plurality of pulsating heat pipe assemblies 130. Each of the plurality of pulsating heat pipe assemblies 130 may be embedded in a corresponding casing such that the number of pulsating heat pipe assemblies 130 is equal to the number of casings 110 in the system 100.

In yet other embodiments, there can be a plurality of pulsating heat pipe assembly 130 where each pulsating heat pipe assembly 130 can be embedded within casings 110. As non-limiting examples, there could be six pulsating heat pipe assemblies 130 and twelve casings 110 or five pulsating heat pipe assemblies 130 and fifteen casings 110.

In yet other embodiments, there can be multiple condenser sections 144 embedded in a casing 110, a fin 120a, and/or the like, and multiple evaporator sections 142 coupled to the interior surface 124b of the casing 110.

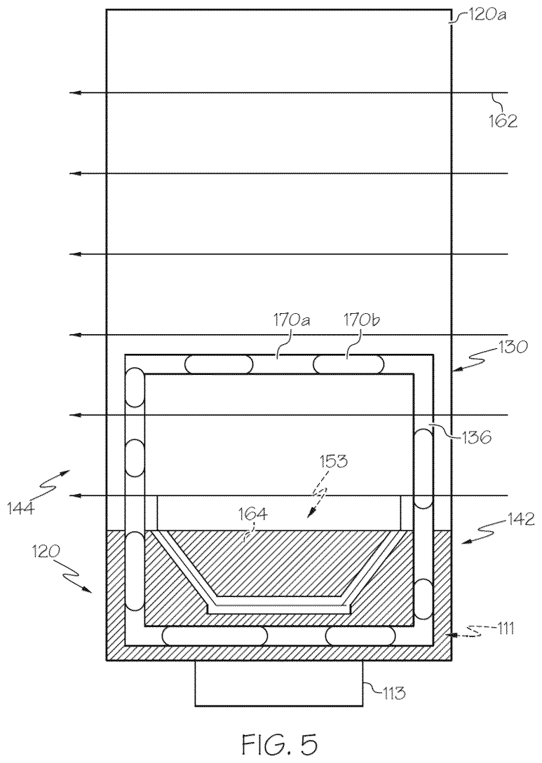

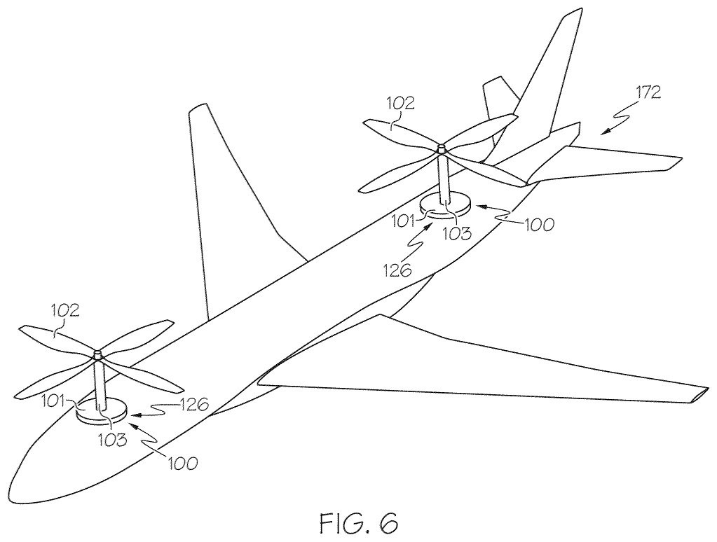

Referring now to FIG. 5, the pulsating heat pipe assembly 130 may contain alternating slugs 170a, 170b, of liquid and vapor, respectively, which may further enhance the cooling effect of the two-part cooling system 126 by increasing the heat transfer from the one or more electronic devices 113 to the plurality of fins 120 via the duct assembly 132, as discussed in greater detail herein.

It should be understood that the pulsating heat pipe assembly 130 is configured to efficiently transfer heat input from the one or more electronic devices 113 to the duct assembly 132, as discussed in greater detail herein.

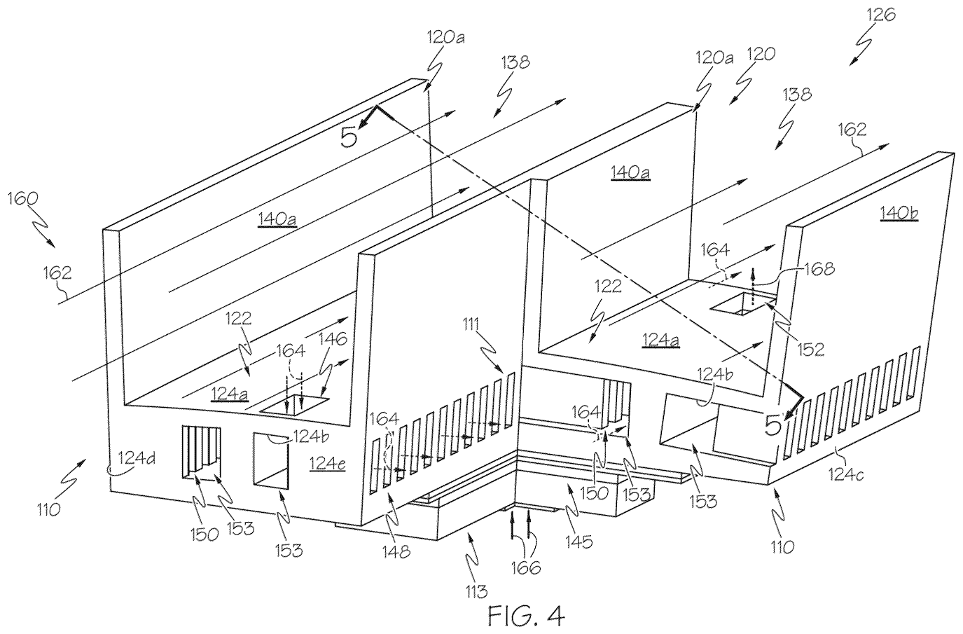

Still referring to FIGS. 2 and 3A-3E, and now to FIG. 4, the duct assembly 132 includes fluid duct 145 that has a duct inlet 146 extending from the exterior surface 124a of the wall 122 in one fin interior cavity 138 and is fluidly coupled via the fluid duct 145 to a duct outlet 152 positioned within another, or different, fin interior cavity 138. The duct inlet 146 fluidly couples the casing interior cavity 111 and the fin interior cavity 138 such that airflow into the fin interior cavity 138 may be directed by the duct inlet 146 and into the casing interior cavity 111. As depicted best in FIG. 4, the duct inlet 146 is positioned on a high pressure side of the fin 120a. In some embodiments, the casing interior cavity 111 includes a plurality of heat enhancing structures, such as a plurality of ribs 150 to assist in heat removal generated by the one or more electronic devices 113. In other embodiments, the casing interior cavity 111 includes a plurality of recesses to assist in heat removal generated by the one or more electronic devices 113. The plurality of ribs 150 may be metal foams, or other porous metal shapes, configured to assist in heat removal generated by the one or more electronic devices 113.

The sidewall surface 124c of the casing 110 includes a plurality of elongated slots 148 or voids to fluidly couple the casing interior cavity 111 to outside of the casing 110. At least portions of the plurality of elongated slots 148 may be positioned to be below or lower than the duct inlet 146 in the vertical direction. Further, the plurality of elongated slots 148 may be positioned such that the airflow exiting the plurality of elongated slots 148 is orthogonal to the airflow entering the duct inlet 146, as best illustrated in FIG. 4.

A duct outlet 152 fluidly couples the casing interior cavity 111 and the fin interior cavity 138 such that airflow from the casing interior cavity 111 may be directed into the fin interior cavity 138 by the duct outlet 152. As depicted best in FIG. 4, the duct outlet 152 is positioned on a low pressure side of the fin 120a. As such, the amount of airflow between the duct inlet 146 and the duct outlet 152 may be dependent on a pressure difference between the duct inlet 146 and the duct outlet 152. That is, in the depicted embodiment, the duct inlet 146 and the duct outlet 152 may be positioned at opposite ends or lengths of the fin interior cavity 138 and may be positioned in different or independent fin interior cavities 138.

Further, a plurality of channels 153 may be positioned to extend within the or fluidly couple to one another and the casing interior cavity 111 or multiple casing interior cavities, as depicted in FIG. 4. Each of the plurality of channels 153 may be configured to transfer heat generated by the one or more electronic devices 113. Further, in some embodiments, each of the plurality of channels 153 may permit airflow to enter and/or to change a pressure to direct airflow as desired. For example, the plurality of channels 153 may be strategically positioned with openings to specific points outside of the casing interior cavity 111 to change a pressure at that opening, assisting and/or causing the airflow to be directed, for instance, out of the casing interior cavity 111 through the plurality of elongated slots 148.

Each of the plurality of channels 153 may be any number of cross sectional shapes, including but not limited to rectangular, circular, or any other cross sectional shape. Further, in some embodiments, each of the plurality of channels 153 may be formed using 3D printing techniques. In other embodiments, each of the plurality of channels 153 may be formed by casting, machining, or any other suitable manufacturing technique.

As such, the pressure difference may be controlled by design. That is, by changing an angle and/or shape of at least one fin 120a of the plurality of fins 120 with respect to the exterior surface 124a, and/or a placement of the duct inlet 146 and/or the duct outlet 152 along a length of the fin 120a alters the pressure difference to a desired air rate flow. Further, the pressure difference may be controlled by adding the plurality of channels 153 at specific positions within the casing 110.

Referring now to FIGS. 4 and 5, in operation, the example two-part cooling system 126 removes heat from the one or more electronic devices 113, such as the power device package 134, via a directed airflow 160 and the pulsating heat pipe assembly 130. The directed airflow 160 includes two types of airflow, one for a fin airflow, as depicted by arrow 162, and ducted airflow, as depicted by arrow 164. The plurality of fins 120 direct the fin airflow 162 between the plurality of fins 120 to travel the length of the fin interior cavity 138 of each fin 120a of the plurality of fins 120 from one of the terminating end surface 124e to the other one of the terminating end surface 124f.

As such, the fin airflow 162 is subject to a pressure defined by or caused from the plurality of fins 120 and directs the fin airflow 162 the length of the casing 110. The ducted airflow 164 may be a portion of the fin airflow 162 that is directed from the fin interior cavity 138 into the duct inlet 146 via a pressure differential between the casing interior cavity 111 and the exterior surface 124a of the casing 110 within the fin interior cavity 138. As depicted, the ducted airflow 164 enters through the duct inlet 146 and into the casing interior cavity 111 to travel or traverse the plurality of channels 153 while passing through or against the plurality of ribs 150 positioned within the casing interior cavity 111 to absorb heat and/or push the heat generated by the one or more electronic devices 113. The generated heat is depicted by arrow 166 in FIG. 4.

The ducted airflow 164 exits the casing interior cavity 111 via the plurality of elongated slots 148, which are fluidly coupled to the plurality of channels 153 and an adjacent casing interior cavity 111 such that the ducted airflow 164 travels through the cavity and the plurality of channels 153 to exit the casing 110 at the duct outlet 152 as a heated airflow, depicted by arrow 168. The heated airflow 168 is pushed away from the casing 110 via the fin airflow 162. It should be understood that the arrangement of the duct inlet 146 on the high pressure side of the fin 120a, the plurality of channels 153, and the duct outlet 152 positioned on the low pressure side of the fin 120a allow for the ducted airflow 164 to travel through the casing 110 to remove the heat 166 generated by the one for more electronic devices 113 from the casing 110.

Referring now to FIG. 6, the system 100 is shown on an eVTOL 172. A plurality of motors 101 coupled by a plurality of propeller shafts 103 to a plurality of propellers 102 may be used. The eVTOL 172 may use the lift from the plurality of propellers 102 to vertically takeoff and land. The plurality of propellers 102 may also provide thrust such that the eVTOL 172 can move forward. The airflow from the propeller 102 may also provide airflow to the plurality of fins 120 (FIG. 1) of the system 100. In an alternative embodiment, the airflow from the propeller 102 may also provide airflow to the fin interior cavity 138, which in turn is directed to the duct assembly 132 (FIG. 4). The airflow may allow for the condenser section 144 to condense the refrigerant inside of each pulsating heat pipe assemblies 130, which can cool the electronic devices 113.

The system 100 may allow for enhanced cooling of electronic devices 113 in electric aircraft, including eVTOL 172. The system 100 can include the example two-part cooling system 126. The example two-part cooling system 126 can further be arranged by a user selecting a desired number of the plurality of fins 120 (FIG. 4), the angle and/or shape of each of the plurality of fins 120 (FIG. 4), and/or the like, to achieve a desired amount of cooling capability of the example two-part cooling system 126. Each of the plurality of fins 120 may be placed in the airflow of the plurality of propellers 102 such that the airflow may further cool the condenser section 144 embedded within the casing via the duct assembly 132 (FIG. 4). The pulsating heat pipe assembly 130 can allow for more efficient heat transfer across the entire fin of each fin 120a (FIG. 4) of the plurality of fins 120 (FIG. 4). This more efficient heat transfer can remove more heat from the electronic devices 113, which can allow the electronic devices 113 to operate more efficiently.

The above-described example two-part cooling system provides a case that includes a plurality of fins extending therefrom, and a plurality of heat transfer enhancing structures, such as channels, positioned within a cavity of the casing. Each of the plurality of fins are configured to induce a pressure differential from one side to the other of the fins to create pressure differences. A duct inlet is positioned on a high pressure side of one fin of a plurality of fins, and a duct outlet is positioned on a low pressure side of a fin of the plurality of fins to permit and guide airflow through the cavity of the case to expel heat from the cavity. Further, an integrated PHP structure is positioned within the case, which are configured to transfer heat from the power device to the plurality of fins.

While particular embodiments have been illustrated and described herein, it should be understood that various other changes and modifications may be made without departing from the spirit and scope of the claimed subject matter. Moreover, although various aspects of the claimed subject matter have been described herein, such aspects need not be utilized in combination. It is therefore intended that the appended claims cover all such changes and modifications that are within the scope of the claimed subject matter.

What is claimed is:

1. A cooling system comprising:
a casing surrounding one or more electronic devices; and
at least two fins extending from an exterior surface of the casing, each of the at least two fins configured to direct an airflow to generate a high pressure zone and a low pressure zone,
wherein the casing includes a duct assembly having a duct inlet and a duct outlet, the duct inlet is configured to be positioned in the high pressure zone and the duct outlet is configured to be positioned in the low pressure zone.

2. The cooling system of claim 1, wherein the casing further comprises:
a casing interior cavity defined by an interior surface of the casing, a plurality of heat enhancing structures extend from the interior surface of the casing.

3. The cooling system of claim 2, wherein at least a portion of the one or more electronic devices in contact at least a portion of the interior surface of the casing.

4. The cooling system of claim 2, wherein the casing further comprises:
a plurality of elongated slots to direct the airflow,
wherein the plurality of elongated slots are positioned to extend through the interior surface and an opposite exterior surface of the casing to fluidly couple the interior cavity and the duct outlet.

5. The cooling system of claim 4, wherein each pair of the at least two fins and the exterior surface of the casing define a fin interior cavity, the duct inlet and the duct outlet positioned in different fin interior cavities.

6. The cooling system of claim 5, further comprising:
at least one pulsating heat pipe, at least a portion of the at least one pulsating heat pipe is positioned within the casing interior cavity.

7. The cooling system of claim 6, wherein each one of the at least one pulsating heat pipe is in a closed loop configuration.

8. The cooling system of claim 7, wherein the casing interior cavity is an evaporator for the at least one pulsating heat pipe and the fin interior cavity is a condenser for the at least one pulsating heat pipe.

9. An electric motor assembly comprising:
a motor housing;
a motor within the motor housing;
a casing having an exterior surface and an opposite interior surface that defines a casing interior cavity;
one or more electronic devices positioned within the casing interior cavity to be surrounded by the interior surface;
at least two fins extending from the exterior surface of the casing, wherein each pair of the at least two fins and the exterior surface of the casing define a fin interior cavity, each of the at least two fins configured to direct an airflow to generate a high pressure zone and a low pressure zone,
wherein the casing includes a duct assembly having a duct inlet and a duct outlet, the duct inlet is configured to be positioned in the high pressure zone and the duct outlet is configured to be positioned in the low pressure zone.

10. The electric motor assembly of claim 9, wherein the casing interior cavity includes a plurality of heat enhancing structures extending from the interior surface.

11. The electric motor assembly of claim 10, wherein the casing further comprises:
a plurality of elongated slots to direct the airflow,
wherein the plurality of elongated slots are positioned to extend through the interior surface and the exterior surface to fluidly couple the casing interior cavity and the duct outlet.

12. The electric motor assembly of claim 11, wherein the duct inlet and the duct outlet are positioned in different fin interior cavities.

13. The electric motor assembly of claim 12, further comprising:
at least one pulsating heat pipe, at least a portion of the at least one pulsating heat pipe is positioned within the casing interior cavity.

14. The electric motor assembly of claim 13, wherein each one of the at least one pulsating heat pipe is in a closed loop configuration.

15. The electric motor assembly of claim 14, wherein the casing interior cavity is an evaporator for the at least one pulsating heat pipe and the fin interior cavity is a condenser for the at least one pulsating heat pipe.

16. The electric motor assembly of claim 9, wherein at least a portion of the one or more electronic devices in contact at least a portion of the interior surface.

17. An electric vertical takeoff and landing vehicle comprising:
an electric motor assembly comprising:
a motor housing;
a motor within the motor housing;
a casing having an exterior surface and an opposite interior surface that defines a casing interior cavity;
one or more electronic devices positioned within the casing interior cavity to be surrounded by the interior surface;
at least two fins extending from the exterior surface of the casing, wherein each pair of the at least two fins and the exterior surface of the casing define a fin interior cavity, each of the at least two fins configured to direct an airflow to generate a high pressure zone and a low pressure zone,
wherein the casing includes a duct assembly having a duct inlet and a duct outlet, the duct inlet is configured to be positioned in the high pressure zone and the duct outlet is configured to be positioned in the low pressure zone.

18. The electric vertical takeoff and landing vehicle of claim 17, wherein the casing interior cavity includes a plurality of heat enhancing structures extending from the interior surface a plurality of elongated slots to direct the airflow, the plurality of elongated slots are positioned to extend through the interior surface and the exterior surface to fluidly couple the casing interior cavity and the duct outlet.

19. The electric vertical takeoff and landing vehicle of claim 18, wherein the duct inlet and the duct outlet are positioned in different fin interior cavities.

20. The electric vertical takeoff and landing vehicle of claim 19, further comprising:
at least one pulsating heat pipe, at least a portion of the at least one pulsating heat pipe is positioned within the casing interior cavity, and each one of the at least one pulsating heat pipe is in a closed loop configuration.
